(19) United States
(12) Patent Application Publication
(10) Pub. No.: US 2024/0414929 A1
(43) Pub. Date: Dec. 12, 2024

(54) VERTICAL ORGANIC TRANSISTOR AND METHOD OF MANUFACTURING THE SAME

(71) Applicants: KOREA RESEARCH INSTITUTE OF STANDARDS AND SCIENCE, Yuseong-gu, Daejeon (KR); KOREA RESEARCH INSTITUTE OF CHEMICAL TECHNOLOGY, Yuseong-gu, Daejeon (KR)

(72) Inventors: Won Suk SHIN, Daejeon (KR); Hang Ken LEE, Daejeon (KR); Chang Eun SONG, Daejeon (KR); Kyung Geun LIM, Busan (KR); Su Hyeon LEE, Seoul (KR)

(21) Appl. No.: 18/397,073

(22) Filed: Dec. 27, 2023

(30) Foreign Application Priority Data
Dec. 29, 2022 (KR) 10-2022-0189179

(51) Int. Cl. H10K 30/82; H10K 30/40

(52) U.S. Cl. CPC H10K 30/82; H10K 30/40

(57) ABSTRACT

The present invention relates to a semiconductor device and a semiconductor material, and more specifically, to an organic semiconductor thin film transistor having a vertical structure, a fusion device of an optical semiconductor material, and a method of manufacturing the same, provides a vertical organic transistor including a substrate, a first electrode layer formed on the substrate, a lower charge transport layer formed on the first electrode layer, a photosensitive layer formed on the lower charge transport layer, an upper charge transport layer formed on the photosensitive layer, a second electrode layer including a base electrode formed on the upper charge transport layer, a plurality of pinholes formed in the base electrode and configured to provide a movement path of charges, and a metal oxide layer surrounding a surface of the base electrode and the pinholes, an organic active layer formed on the second electrode layer, and a third electrode layer formed on the organic active layer.

### CROSS REFERENCE TO RELATED APPLICATION

The present application claims priority to Korean Patent Application No. 10-2022-0189179, filed on Dec. 29, 2022, the entire contents of which is incorporated herein for all purposes by this reference.

### BACKGROUND OF THE INVENTION

### Field of the Invention

The present invention relates to a semiconductor device and a semiconductor material, and more specifically, to an organic semiconductor thin film transistor having a vertical structure, a fusion device of an optical semiconductor material, and a method of manufacturing the same.

### Description of the Related Art

Photodiodes using organic materials largely include a photo transistor type (organic photo transistor (OPT)), a diode type (organic photo diode (OPD)), a photo conductor type (organic photo conductor (OPC)), and the like.

The most widely studied diode type (OPD) has an excellent photosensitivity and response speed, but has a disadvantage in that external quantum efficiency (EQE) becomes 100% or less due to an internal loss during photoelectric conversion, and there is a limit to obtaining high detection performance due to a high dark current.

On the other hand, the photo transistor type (OPT) devices may obtain external quantum efficiency (EQE) of 100% or more due to internal photocurrent amplification using a gate electrode, but there is a disadvantage in that it is difficult to apply the photo transistor type (OPT) to devices requiring a fast switching speed due to a slow response speed and it is difficult to apply the photo transistor type (OPT) to small portable devices or the like due to a high driving voltage.

### SUMMARY OF THE INVENTION

The present invention is directed to providing a vertical organic transistor capable of securing fast switching speed and low-power driving characteristics and simultaneously achieving high photosensitivity and detection performance characteristics as well as a fast response speed, and a method of manufacturing the same.

An embodiment of the present invention may provide a vertical organic transistor including a substrate, a first electrode layer formed on the substrate, a lower charge transport layer formed on the first electrode layer, a photosensitive layer formed on the lower charge transport layer, an upper charge transport layer formed on the photosensitive layer, a second electrode layer including a base electrode formed on the upper charge transport layer, a plurality of pinholes formed in the base electrode and configured to provide a movement path of charges, and a metal oxide layer surrounding a surface of the base electrode and the pinholes, an organic active layer formed on the second electrode layer, and a third electrode layer formed on the organic active layer.

According to the embodiment of the present invention, the photosensitive layer may include organic low-molecular and high-molecular donor materials, organic low-molecular and high-molecular acceptor materials, organic-inorganic hybrid perovskite materials, quantum dot materials, or 2-dimensional (2D) semiconductor materials.

According to the embodiment of the present invention, the metal oxide layer may include at least one selected from the group consisting of yttrium oxide (Y₂O₃), aluminum oxide (Al₂O₃, AlOₓ, or AlₓO_{y}), magnesium oxide (MgOₓ), zinc oxide (ZnO), tin oxide (SnO), iron oxide (Fe₂O₃ or FeOₓ), titanium oxide (TiOₓ), zirconium oxide (ZrO₂), chromium oxide (Cr₂O₃), hafnium oxide (HfO), beryllium oxide (BeO), tungsten oxide (WOₓ), copper oxide (CuOₓ), silicone oxide (SiOₓ), and nickel oxide (NiOₓ) (x and y are rational numbers between 1 and 3).

According to the embodiment of the present invention, the organic active layer may be formed by using n-type and p-type high-molecular materials or n-type and p-type low-molecular materials.

According to the embodiment of the present invention, sensitivity of the vertical organic transistor including the photosensitive layer may be in a range of 1×10¹ to 1×10⁷, responsivity thereof may be in a range of 1×10¹ to 6×10³ A/W, detectivity thereof may be in a range of 1×10¹ to 1×10¹⁶ Jonse, mobility thereof may be in a range of 1×10⁻⁴ to 3.51×10⁻¹ cm²/Vs, and a cutoff frequency may be in a range of 100 Hz to 3 GHz.

An embodiment of the present invention may provide a method of manufacturing a vertical organic transistor including providing a substrate, forming a first electrode layer on the substrate, forming a lower charge transport layer on the first electrode layer, forming a photosensitive layer on the lower charge transport layer, forming an upper charge transport layer on the photosensitive layer, forming a second electrode layer including a base electrode, a plurality of pinholes formed in the base electrode and configured to provide a movement path of charges, and a metal oxide layer surrounding a surface of the base electrode and the pinholes on the upper charge transport layer, forming an organic active layer on the second electrode layer, and forming a third electrode layer on the organic active layer.

According to the embodiment of the present invention, the photosensitive layer may be formed on the lower charge transport layer. The photosensitive layer may include organic low-molecular and high-molecular donor materials, organic low-molecular and high-molecular acceptor materials, organic-inorganic hybrid perovskite materials, quantum dot materials, or 2-dimensional (2D) semiconductor materials.

According to the embodiment of the present invention, the metal oxide layer may include at least one selected from the group consisting of yttrium oxide (Y₂O₃), aluminum oxide (Al₂O₃, AlOₓ, or AlₓO_{y}), magnesium oxide (MgOₓ), zinc oxide (ZnO), tin oxide (SnO), iron oxide (Fe₂O₃ or FeOₓ), titanium oxide (TiOₓ), zirconium oxide (ZrO₂), chromium oxide (Cr₂O₃), hafnium oxide (HfO), beryllium oxide (BeO), tungsten oxide (WOₓ), copper oxide (CuOₓ), silicone oxide (SiOₓ), and nickel oxide (NiOₓ) (x and y are rational numbers between 1 and 3).

According to the embodiment of the present invention, the organic active layer may be formed by using n-type and p-type high-molecular materials or n-type and p-type low-molecular materials.

Another embodiment of the present invention provides a vertical organic transistor including a substrate, a first electrode layer formed on the substrate, an organic active layer formed on the first electrode layer, a second electrode layer including a base electrode formed on the organic active layer, a plurality of pinholes formed in the base electrode and configured to provide a movement path of charges, and a metal oxide layer surrounding a surface of the base electrode and the pinholes, a lower charge transport layer formed on the second electrode layer, a photosensitive layer formed on the lower charge transport layer, an upper charge transport layer formed on the photosensitive layer, and a third electrode layer formed on the upper charge transport layer.

According to another embodiment of the present invention, the organic active layer may be formed by using n-type and p-type high-molecular materials or n-type and p-type low-molecular materials.

According to another embodiment of the present invention, the metal oxide layer may include at least one selected from the group consisting of yttrium oxide (Y₂O₃), aluminum oxide (Al₂O₃, AlOₓ, or AlₓO_{y}), magnesium oxide (MgOₓ), zinc oxide (ZnO), tin oxide (SnO), iron oxide (Fe₂O₃ or FeOₓ), titanium oxide (TiOₓ), zirconium oxide (ZrO₂), chromium oxide (Cr₂O₃), hafnium oxide (HfO), beryllium oxide (BeO), tungsten oxide (WOₓ), copper oxide (CuOₓ), silicone oxide (SiOₓ), and nickel oxide (NiOₓ) (x and y are rational numbers between 1 and 3).

According to another embodiment of the present invention, the photosensitive layer may include organic low-molecular and high-molecular donor materials, organic low-molecular and high-molecular acceptor materials, organic-inorganic hybrid perovskite materials, quantum dot materials, or 2-dimensional (2D) semiconductor materials.

According to another embodiment of the present invention, sensitivity of the vertical organic transistor including the photosensitive layer may be in a range of 1×10¹ to 1×10⁷, responsivity thereof may be in a range of 1×10¹ to 6×10³ A/W, detectivity thereof may be in a range of 1×10¹ to 1×10¹⁶ Jonse, mobility thereof may be in a range of 1×10⁻⁴ to 3.51×10⁻¹ cm²/Vs, and a cutoff frequency may be in a range of 100 Hz to 3 GHz.

### BRIEF DESCRIPTION OF THE DRAWINGS

FIG. 1 is a cross-sectional view of a vertical organic thin film transistor according to an embodiment of the present invention.

FIGS. 2A to 2E are cross-sectional views of a manufacturing process of the vertical organic thin film transistor according to the embodiment of the present invention.

FIG. 3 is a flowchart of the manufacturing process of the vertical organic thin film transistor according to the embodiment of the present invention.

FIG. 4 is a cross-sectional view of a vertical organic thin film transistor according to another embodiment of the present invention.

FIGS. 5A to 5E are cross-sectional views of a manufacturing process of the vertical organic thin film transistor according to another embodiment of the present invention.

FIG. 6 is a flowchart of the manufacturing process of the vertical organic thin film transistor according to another embodiment of the present invention.

FIG. 7 is a view illustrating a change in a collector current/base current according to a base-emitter voltage of the vertical organic transistor in the embodiment of the present invention.

FIG. 8 is a view illustrating a change in current according to a voltage when only an organic photodiode is present in the embodiment of the present invention.

FIG. 9 is a view illustrating dark currents and photocurrents (light intensity of 100 mA/cm²) of the collector current and the base current according to the base-emitter voltage of the vertical organic transistor in the embodiment of the present invention.

FIG. 10 is a view illustrating dark currents and photocurrents (light intensity of 100 mA/cm²) of the collector current and the base current according to the base-emitter voltage of the vertical organic transistor in the embodiment of the present invention.

FIG. 11 is a view illustrating a drain-emitter current according to a light pulse of the vertical organic transistor over time in the embodiment of the present invention.

FIG. 12 is a view illustrating photosensitivity according to the base-emitter voltage of the vertical organic transistor in the embodiment of the present invention.

FIG. 13 is a view illustrating responsivity according to the base-emitter voltage of the vertical organic transistor in the embodiment of the present invention.

FIG. 14 is a view illustrating detectivity according to the base-emitter voltage of the vertical organic transistor in the embodiment of the present invention.

FIG. 15 is a view illustrating a frequency according to a gate voltage V_{g} of the vertical organic transistor in the embodiment of the present invention.

FIG. 16 is a view illustrating mobility according to the gate voltage V_{g} of the vertical organic transistor in the embodiment of the present invention.

### DETAILED DESCRIPTION OF THE INVENTION

Hereinafter, exemplary embodiments of the present invention will be described in detail with reference to the accompanying drawings.

However, the technical spirit of the present invention is not limited to some of the described embodiments, but may be implemented in various different forms, and one or more of the components among the embodiments may be used by being selectively coupled or substituted without departing from the scope of the technical spirit of the present invention.

In addition, the terms (including technical and scientific terms) used in embodiments of the present invention may be construed as meaning that may be generally understood by those skilled in the art to which the present invention pertains unless explicitly specifically defined and described, and the meanings of the commonly used terms, such as terms defined in a dictionary, may be construed in consideration of contextual meanings of related technologies.

In addition, the terms used in the embodiments of the present invention are for describing the embodiments and are not intended to limit the present invention.

In the specification, a singular form may include a plural form unless otherwise specified in the phrase, and when described as “at least one (or one or more) of A, B, and C,” one or more among all possible combinations of A, B, and C may be included.

In addition, terms such as first, second, A, B, (a), and (b) may be used to describe components of the embodiments of the present invention.

These terms are only for the purpose of distinguishing one component from another component, and the nature, sequence, order, or the like of the corresponding components is not limited by these terms.

In addition, when a first component is described as being “connected,” “coupled,” or “joined” to a second component, it may include a case in which the first component is directly connected, coupled, or joined to the second component, but also a case in which the first component is “connected,” “coupled,” or “joined” to the second component by other components present between the first component and the second component.

In addition, when a certain component is described as being formed or disposed on “on (above)” or “below (under)” another component, the terms “on (above)” or “below (under)” may include not only a case in which two components are in direct contact with each other, but also a case in which one or more other components are formed or disposed between the two components. In addition, when described as “on (above) or below (under),” it may include the meaning of not only an upward direction but also a downward direction based on one component.

Hereinafter, embodiments will be described in detail with reference to the accompanying drawings, and the same or corresponding components are denoted by the same reference numeral regardless of the reference numerals, and overlapping descriptions thereof will be omitted.

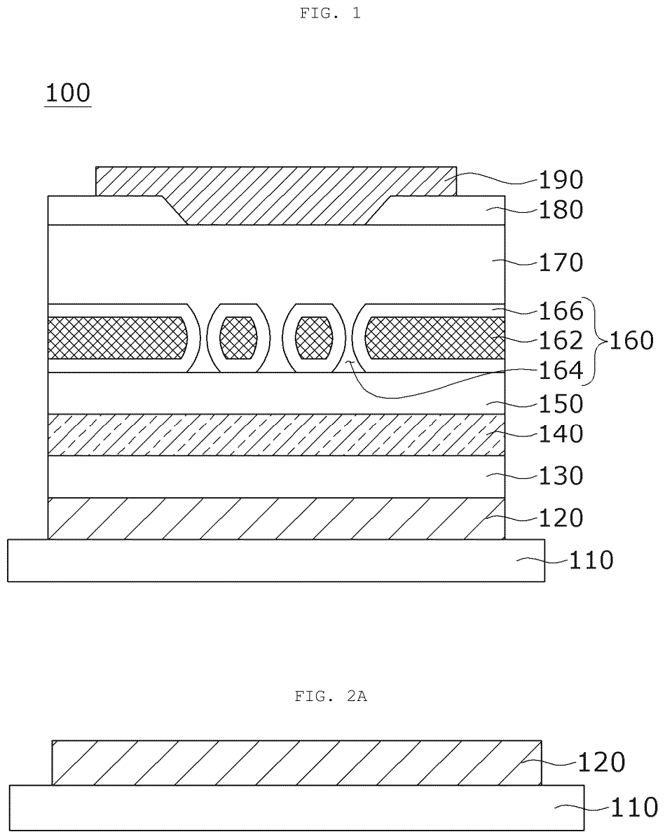

FIG. 1 is a cross-sectional view of a vertical organic thin film transistor provided with an organic photodiode (OPD) according to an embodiment of the present invention.

Referring to FIG. 1, a vertical organic thin film transistor 100 provided with an OPD according to an embodiment of the present invention is a device for absorbing light and may include a substrate 110, a first electrode layer 120, a lower charge transport layer 130, a photosensitive layer 140, an upper charge transport layer 150, a second electrode layer 160, an organic active layer 170, and a third electrode layer 190.

Here, the first electrode layer 120, the lower charge transport layer 130, the organic photosensitive layer 140, the upper charge transport layer 150, and the third electrode layer 190 may form an organic photodiode.

The substrate 110 may be a base for supporting the overall structure of the vertical organic thin film transistor 100. For example, the substrate 110 may be made of glass, quartz, polymer resin (e.g., plastic), silicone, or the like.

The first electrode layer 120 may be disposed on an upper surface of the substrate 110. For example, the first electrode layer 120 may be a collector electrode.

The lower charge transport layer 130 may be formed on the first electrode layer 120. The first electrode layer 120 may be, for example, a transparent electrode such as indium tin oxide (ITO).

The lower charge transport layer 130 is a hole transport layer and may be a material layer having high hole mobility and light-emitting characteristics. The lower charge transport layer 130 may be a quantum dot layer, a monomolecular layer, or a polymer layer.

The organic photosensitive layer 140 may be formed on the lower charge transport layer 130. The photosensitive layer 240 may be made of not only organic semiconductor materials such as organic low-molecular and high-molecular donor materials and organic low-molecular and high-molecular acceptor materials used in the OPD, but also CsPbBr₃, which is a perovskite quantum dot, or C₃N₄, which is a two-dimensional material.

The organic photosensitive layer 140 has an advantage in that it is possible to easily adjust an open voltage current density and the like required for a device because various characteristics such as a bandgap, solubility, crystallinity, and a coating property are easily adjusted compared to other materials and has an advantage in that process and material costs are low because it is possible to implement large areas with low costs.

The upper charge transport layer 150 may be formed on the organic photosensitive layer 140. The upper charge transport layer 150 is an electron transport layer, a material layer having a high electron mobility characteristic, and may be a quantum dot layer, a monomolecular layer, or a polymer layer.

An energy level of the upper charge transport layer 150 is lower than that of the lower charge transport layer 130. When a voltage is applied to the lower charge transport layer 130 and the upper charge transport layer 150 according to this difference in energy level, charges (i.e., electrons/holes) aggregates (i.e. accumulates) at an interface of the upper charge transport layer 150 and the lower charge transport layer 130.

For example, the electrons aggregate at the upper charge transport layer 150 side, and the holes aggregate at the lower charge transport layer 130 side.

The aggregation of the charges can improve the binding efficiency of the electrons and the holes, thereby increasing the light-emitting efficiency of a light-emitting device.

Moreover, by providing the organic photosensitive layer 140 between the upper charge transport layer 150 and the lower charge transport layer 130, it is possible to increase external quantum efficiency according to the charges aggregating at the interface of the upper charge transport layer 150 and the lower charge transport layer 130. In addition, by transmitting light generated from the upper charge transport layer 150 and the lower charge transport layer 130 to the organic photosensitive layer 140, it is possible to improve the external quantum efficiency of the organic photosensitive layer 140.

In other words, it is possible to improve the external quantum efficiency of the organic photosensitive layer 140 by the charges aggregating at the interface of the upper charge transport layer 150 and the lower charge transport layer 130, and Forster resonant energy transfer (FRET) between the interface between the upper charge transport layer 150 and the organic photosensitive layer 140 and the interface between the lower charge transport layer 130 and the organic photosensitive layer 140.

As described above, according to the embodiment of the present invention, when a voltage is applied to an anode and a cathode, holes injected from the anode may move to the photosensitive layer EML through the lower charge transport layer HTL, and electrons injected from the cathode may move to the photosensitive layer EML through the upper charge transport layer ETL. The holes and the electrons may generate excitons by recombining in the photosensitive layer EML. Light may be emitted when the exciton falls from an excited state to a ground state.

In order for the OPD having the above-described structure to have excellent efficiency and/or long life, the injection and movement of the holes and the electrons should be balanced.

In the embodiment of the present invention, for the OPD, it is possible to provide an organic thin film transistor provided with the OPD including the photosensitive layer and two or more charge transport layers ETL, which increase efficiency, for example, external quantum efficiency (EQE) and have a low operation voltage and long life.

In addition, the second electrode layer 160 may be formed on the upper charge transport layer 150.

The second electrode layer 160 may include a base electrode layer 162, which is a transmission electrode, a plurality of pinholes 164 formed in the base electrode layer 162 to provide a movement path of charges, and a metal oxide layer 166 surrounding the entire surface including an upper surface and a lower surface of the base electrode layer 162 and the pinholes 164.

The base electrode layer 162 may be, for example, any one of Al, Ti, Mg, Cu, Ni, Si, Cr, Hf, Sn, Y, and Zn.

In addition, the metal oxide layer 166 may contain, for example, at least one selected from the group consisting of yttrium oxide (Y₂O₃), aluminum oxide (Al₂O₃, AlOₓ, or AlₓO_{y}), magnesium oxide (MgOₓ), zinc oxide (ZnO), tin oxide (SnO), iron oxide (Fe₂O₃ or FeOₓ), titanium oxide (TiOₓ), zirconium oxide (ZrO₂), chromium oxide (Cr₂O₃), hafnium oxide (HfO), beryllium oxide (BeO), tungsten oxide (WOₓ), copper oxide (CuOₓ), silicone oxide (SiOₓ), and nickel oxide (NiOₓ) (x and y are rational numbers between 1 and 3).

In the embodiment of the present invention, a case in which the base electrode layer 162 is made of Al and the metal oxide layer 166 is made of AlOₓ is described as an example, but is not limited thereto, and the organic thin film transistor 100 according to the present invention may be manufactured through the above-described type of the base electrode layer 162 and the metal oxide layer 166.

The pin hole 164 may have a size of several nanometers and provide the movement path of charges between the electrode layers. The second charge transport layer 150 and the organic active layer 170 to be described below may come into contact with each other through the pinhole 164 formed in the base electrode layer 162.

In addition, the metal oxide layer 166 may grow on an exposed surface (i.e., including a side surface of the pinhole) of the pinhole 164 by several nanometers and function as a dielectric layer on the surface of the base electrode layer 162 while maintaining the electron movement path.

The organic active layer 170, which is the organic semiconductor layer, may be disposed on an upper surface of the second electrode layer 160.

The organic active layer 170 may be disposed along the upper surface of the second electrode layer 160.

The organic active layer 170 may have high charge mobility and may be made of a material that facilitates charge injection. The organic active layer 170 may be formed by using a semiconductor low-molecular material such as oligothiophene or pentacene or a semiconductor high-molecular material such as polythiophene or using n-type and p-type high-molecular materials and n-type and p type low-molecular materials.

Alternatively, a layer of high efficiency n-type doping W2(hpp)4 (20 nm thick, 1 wt % in C₆₀) may be applied to the organic active layer 170 for improved electron injection.

In addition, the insulating layer 180 may be formed between a portion of the third electrode layer 190 to be described below and the organic active layer 170.

The insulating layer 180 may be formed along a portion of an interface between the third electrode layer 190 and the organic active layer 170 to determine a contact area between the third electrode layer 190 and the organic active layer 170. The insulating layer 180 may be made of a material that has excellent insulating properties, does not affect the organic active layer 170, and enables pattern formation. For example, the insulating layer 180 may be formed through the silicone metal oxide layer 166 through vacuum deposition.

In addition, the insulating layer 180 may function as the insulating layer 180 by leaving a photoresin material that does not affect the organic active layer 170 in a form that covers the organic active layer 170 through photoetching.

Alternatively, the insulating layer 180 having a desired pattern may be formed through an etching method using the photoresin material after an organic insulating film using an insulating polymer, polymer, or the like may be formed on the organic active layer 170.

In addition, the third electrode layer 190 may be formed on the organic active layer 170. For example, the third electrode layer 190 may be an emitter electrode.

The third electrode layer 190 may be made of, for example, gold (Au), copper (Cu), aluminum (Al), aluminum alloy (Al-alloy), molybdenum (Mo), chromium (Cr), indium tin oxide (ITO), titanium (Ti), neodymium (AlNd), and silver (Ag) or formed as a double layer made of copper (Cu) and titanium (Ti), gold (Au) and indium tin oxide (ITO), molybdenum (Mo) and AlNd (neodymium), gold (Au) and indium tin oxide (ITO), and molybdenum (Mo) and neodymium (AlNd). The third electrode layer 190 may be formed by vacuum deposition, but is not limited thereto.

As described above, according to the vertical organic transistor according to the embodiments of the present invention, it is possible to secure fast switching speed and low-power driving characteristics by vertically orientating the transistor that is present horizontally.

In addition, according to the vertical organic transistor according to the embodiments of the present invention, by bonding the organic thin film transistor on the OPD and amplify the photocurrent of the OPD, it is possible to simultaneously achieve the high photosensitivity and detection performance characteristics as well as the fast response speed of the vertical organic thin film transistor.

A method of manufacturing the vertical organic transistor formed by the above configuration will be described with reference to the accompanying drawings as follows.

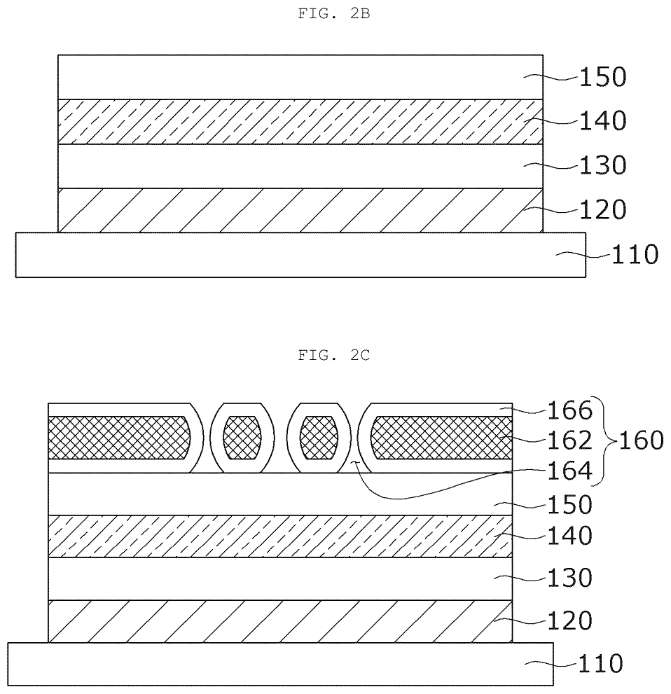

FIGS. 2A to 2E are cross-sectional views of a manufacturing process of the vertical organic thin film transistor according to the embodiment of the present invention.

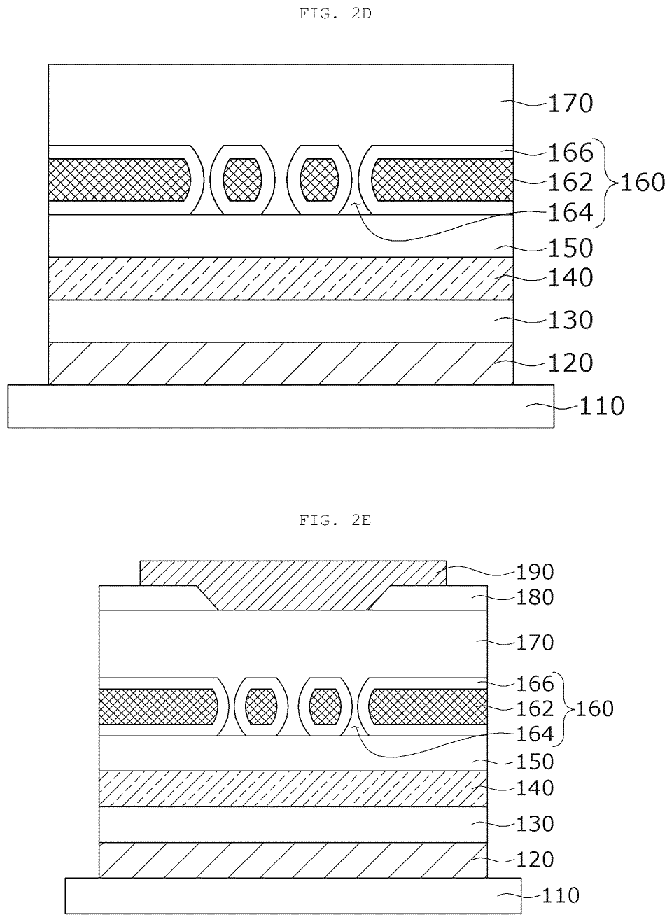

FIG. 3 is a flowchart of the manufacturing process of the vertical organic thin film transistor according to the embodiment of the present invention.

In the method of manufacturing the organic transistor according to the embodiment of the present invention, referring to FIGS. 2A and 3, the substrate 110 is first provided (S110).

The substrate 110 may be a base for supporting the overall structure of the vertical organic thin film transistor 100. For example, the substrate 110 may be made of glass, quartz, polymer resin (e.g., plastic), silicone, or the like.

Next, referring to FIGS. 2A and 3, the first electrode layer 120 may be formed on the substrate 110 (S120). For example, the first electrode layer 120 may be a collector electrode.

The first electrode layer 120 may be formed by using, for example, a transparent electrode material such as ITO.

Next, referring to FIGS. 2B and 3, the lower charge transport layer 130 may be formed on the first electrode layer 120 (S130). The lower charge transport layer 130 is a hole transport layer and may be a material layer having high hole mobility and light-emitting characteristics. The lower charge transport layer 130 may be a quantum dot layer, a monomolecular layer, or a polymer layer.

Next, the organic photosensitive layer 140 may be formed on the lower charge transport layer 130 (S140). Materials for the formation of the photosensitive layer 240 may include not only organic semiconductor materials such as organic low-molecular and high-molecular donor materials and organic low-molecular and high-molecular acceptor materials used in the OPD, but also CsPbBr₃, which is a perovskite quantum dot, or C₃N₄, which is a two-dimensional material.

Next, the upper charge transport layer 150 may be formed on the organic photosensitive layer 140. The upper charge transport layer 150 is an electron transport layer, a material layer having a high electron mobility characteristic, and may be a quantum dot layer, a monomolecular layer, or a polymer layer.

An energy level of the upper charge transport layer 150 is lower than that of the lower charge transport layer 130. When a voltage is applied to the lower charge transport layer 130 and the upper charge transport layer 150 according to this difference in energy level, charges (i.e., electrons/holes) aggregates (i.e. accumulates) at an interface of the upper charge transport layer 150 and the lower charge transport layer 130.

For example, the electrons aggregate at the upper charge transport layer 150 side, and the holes aggregate at the lower charge transport layer 130 side.

The aggregation of the charges can improve the binding efficiency of the electrons and the holes, thereby increasing the efficiency of the photodiode device.

Moreover, by providing the organic photosensitive layer 140 between the upper charge transport layer 150 and the lower charge transport layer 130, it is possible to increase external quantum efficiency according to the charges aggregating at the interface of the upper charge transport layer 150 and the lower charge transport layer 130. In addition, by transmitting light generated from the upper charge transport layer 150 and the lower charge transport layer 130 to the organic photosensitive layer 140, it is possible to improve the external quantum efficiency of the organic photosensitive layer 140.

In other words, it is possible to improve the external quantum efficiency of the organic photosensitive layer 140 by the charges aggregating at the interface of the upper charge transport layer 150 and the lower charge transport layer 130, and Forster resonant energy transfer (FRET) between the interface between the upper charge transport layer 150 and the organic photosensitive layer 140 and the interface between the lower charge transport layer 130 and the organic photosensitive layer 140.

Next, referring to FIGS. 2C and 3, the second electrode layer 160 may be formed on the upper charge transport layer 150 (S150).

The second electrode layer 160 may include a base electrode layer 162, which is a transmission electrode, a plurality of pinholes 164 formed in the base electrode layer 162 to provide a movement path of charges, and a metal oxide layer 166 surrounding the entire surface including an upper surface and a lower surface of the base electrode layer 162 and the pinholes 164.

The base electrode layer 162 may be, for example, any one of Al, Ti, Mg, Cu, Ni, Si, Cr, Hf, Sn, Y, and Zn.

In addition, the metal oxide layer 166 may contain, for example, at least one selected from the group consisting of yttrium oxide (Y₂O₃), aluminum oxide (Al₂O₃, AlOₓ, or AlₓO_{y}), magnesium oxide (MgOₓ), zinc oxide (ZnO), tin oxide (SnO), iron oxide (Fe₂O₃ or FeOₓ), titanium oxide (TiOₓ), zirconium oxide (ZrO₂), chromium oxide (Cr₂O₃), hafnium oxide (HfO), beryllium oxide (BeO), tungsten oxide (WOₓ), copper oxide (CuOₓ), silicone oxide (SiOₓ), and nickel oxide (NiOₓ) (x and y are rational numbers between 1 and 3).

In the embodiment of the present invention, a case in which the base electrode layer 162 is made of Al and the metal oxide layer 166 is made of AlOₓ is described as an example, but is not limited thereto, and the organic thin film transistor 100 according to the present invention may be manufactured through the above-described type of the base electrode layer 162 and the metal oxide layer 166.

The pin hole 164 may have a size of several nanometers and provide the movement path of charges between the electrode layers. The upper charge transport layer 150 and the organic active layer 170 to be described below may come into contact with each other through the pinhole 164 formed in the base electrode layer 162.

In addition, the metal oxide layer 166 may grow on an exposed surface (i.e., including a side surface of the pinhole) of the pinhole 164 by several nanometers and function as a dielectric layer on the surface of the base electrode layer 162 while maintaining the electron movement path.

Next, referring to FIGS. 2D and 3, the organic active layer 170, which is an organic semiconductor layer, may be formed on the second electrode layer 160 (S160). In this case, the organic active layer 170 may be formed along the upper surface of the second electrode layer 160.

The organic active layer 170 may have high charge mobility and may be made of a material that facilitates charge injection. The organic active layer 170 may be formed by using a semiconductor low-molecular material such as oligothiophene or pentacene or a semiconductor high-molecular material such as polythiophene or using n-type and p-type high-molecular materials and n-type and p type low-molecular materials.

Alternatively, a layer of high efficiency n-type doping W2(hpp)4 (20 nm thick, 1 wt % in C₆₀) may be applied to the organic active layer 170 for improved electron injection.

Next, referring to FIGS. 2E and 3, the insulating layer 180 may be formed on the third electrode layer 190 to be described below and the organic active layer 170.

The insulating layer 180 may be formed along a portion of an interface between the third electrode layer 190 and the organic active layer 170 to determine a contact area between the third electrode layer 190 and the organic active layer 170.

The insulating layer 180 may be made of a material that has excellent insulating properties, does not affect the organic active layer 170, and enables pattern formation. For example, the insulating layer 180 may be formed through the silicone metal oxide layer 166 through vacuum deposition.

In addition, the insulating layer 180 may function as the insulating layer 180 by leaving a photoresin material that does not affect the organic active layer 170 in a form that covers the organic active layer 170 through photoetching. Alternatively, the insulating layer 180 having a desired pattern may be formed through an etching method using the photoresin material after an organic insulating film using an insulating polymer, polymer, or the like may be formed on the organic active layer 170.

Next, referring to FIGS. 2E and 3, the third electrode layer 190 may be formed on the organic active layer 170. The third electrode layer 190 may be, for example an emitter electrode.

The third electrode layer 190 may be made of, for example, gold (Au), copper (Cu), aluminum (Al), aluminum alloy (Al-alloy), molybdenum (Mo), chromium (Cr), indium tin oxide (ITO), titanium (Ti), neodymium (AlNd), and silver (Ag) or formed as a double layer made of copper (Cu) and titanium (Ti), gold (Au) and indium tin oxide (ITO), molybdenum (Mo) and AlNd (neodymium), gold (Au) and indium tin oxide (ITO), and molybdenum (Mo) and neodymium (AlNd). The third electrode layer 190 may be formed by vacuum deposition, but is not limited thereto.

Meanwhile, a vertical organic transistor according to another embodiment of the present invention will be described with reference to the accompanying drawings.

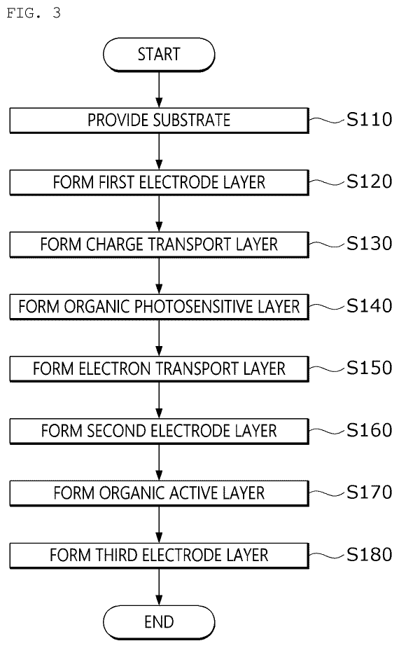

FIG. 4 is a cross-sectional view of a vertical organic thin film transistor provided with an OPD according to another embodiment of the present invention.

Referring to FIG. 4, a vertical organic thin film transistor 200 provided with an OPD according to another embodiment of the present invention is a device for absorbing light and may include a substrate 210, a first electrode layer 220, an organic active layer 230, a second electrode layer 240, a lower charge transport layer 250, an organic photosensitive layer 260, an upper charge transport layer 270, and a third electrode layer 280.

Here, the lower charge transport layer 250, the organic photosensitive layer 260, and the upper charge transport layer 270 may form an organic photodiode.

The substrate 210 may be a base for supporting the overall structure of the organic thin film transistor 200. For example, the substrate 110 may be made of glass, quartz, polymer resin (e.g., plastic), silicone, or the like.

The first electrode layer 220 may be disposed on an upper surface of the substrate 210. For example, the first electrode layer 220 may be a collector electrode. The first electrode layer 220 may be, for example, a transparent electrode such as ITO.

The organic active layer 170, which is the organic semiconductor layer, may be disposed on an upper surface of the first electrode layer 220.

The organic active layer 230 may have high charge mobility and may be made of a material that facilitates charge injection. The organic active layer 230 may be formed by using a semiconductor low-molecular material such as oligothiophene or pentacene or a semiconductor high-molecular material such as polythiophene or using n-type and p-type high-molecular materials and n-type and p type low-molecular materials.

Alternatively, a layer of high efficiency n-type doping W2(hpp)4 (20 nm thick, 1 wt % in C₆₀) may be applied to the organic active layer 230 for improved electron injection.

In addition, the second electrode layer 240 may be formed on the organic active layer 230.

The second electrode layer 240 may include a base electrode layer 242, which is a transmission electrode, a plurality of pinholes 244 formed in the base electrode layer 242 to provide a movement path of charges, and a metal oxide layer 246 surrounding the entire surface including an upper surface and a lower surface of the base electrode layer 242 and the pinholes 244.

The base electrode layer 242 may be, for example, any one of Al, Ti, Mg, Cu, Ni, Si, Cr, Hf, Sn, Y, and Zn.

In addition, the metal oxide layer 246 may contain, for example, at least one material selected from the group consisting of yttrium oxide (Y₂O₃), aluminum oxide (Al₂O₃, AlOₓ, or AlₓO_{y}), magnesium oxide (MgOₓ), zinc oxide (ZnO), tin oxide (SnO), iron oxide (Fe₂O₃ or FeOₓ), titanium oxide (TiOₓ), zirconium oxide (ZrO₂), chromium oxide (Cr₂O₃), hafnium oxide (HfO), beryllium oxide (BeO), tungsten oxide (WOₓ), copper oxide (CuOₓ), silicone oxide (SiOₓ), and nickel oxide (NiOₓ) (x and y are rational numbers between 1 and 3).

In the embodiment of the present invention, a case in which the base electrode layer 242 is made of Al and the metal oxide layer 246 is made of AlOₓ is described as an example, but is not limited thereto, and it goes without saying that the vertical organic thin film transistor 200 according to the present invention may be manufactured through the above-described type of the base electrode layer 242 and the metal oxide layer 246.

The pin hole 244 may have a size of several nanometers and provide the movement path of charges between the electrode layers. The organic active layer 230 and the lower charge transport layer 250 to be described below may come into contact with each other through the pinhole 244 formed in the base electrode layer 242.

In addition, the metal oxide layer 246 may grow on an exposed surface (i.e., including a side surface of the pinhole) of the pinhole 244 by several nanometers and function as a dielectric layer on the surface of the base electrode layer 242 while maintaining the electron movement path.

The lower charge transport layer 250 may be formed on the second electrode layer 240.

The lower charge transport layer 250 is an electron transport layer and may be a material layer having a high electron mobility characteristic. The lower charge transport layer 250 may be a quantum dot layer, a monomolecular layer, or a polymer layer.

The organic photosensitive layer 260 may be formed on the lower charge transport layer 250. Materials for the formation of the photosensitive layer 260 may include not only organic semiconductor materials such as organic low-molecular and high-molecular donor materials and organic low-molecular and high-molecular acceptor materials used in the OPD, but also CsPbBr₃, which is a perovskite quantum dot, or C₃N₄, which is a two-dimensional material.

The upper charge transport layer 270 may be formed on the organic photosensitive layer 260. The upper charge transport layer 270 is a hole transport layer, a material layer having a high hole mobility characteristic, and may be a quantum dot layer, a monomolecular layer, or a polymer layer.

An energy level of the upper charge transport layer 270 is lower than that of the lower charge transport layer 250. When a voltage is applied to the upper charge transport layer 270 and the lower charge transport layer 250 according to this difference in energy level, charges (i.e., electrons/holes) aggregates (i.e. accumulates) at an interface of the lower charge transport layer 250 and the upper charge transport layer 270.

For example, the electrons aggregate at the lower charge transport layer 250 side, and the holes aggregate at the upper charge transport layer 270 side.

The aggregation of the charges can improve the binding efficiency of the electrons and the holes, thereby increasing the light efficiency of the device.

Moreover, by providing the organic photosensitive layer 260 between the lower charge transport layer 250 and the upper charge transport layer 270, it is possible to increase external quantum efficiency according to the charges aggregating at the interface of the lower charge transport layer 250 and the upper charge transport layer 270. In addition, by transmitting light generated from the lower charge transport layer 250 and the upper charge transport layer 270 to the organic photosensitive layer 260, it is possible to improve the external quantum efficiency (EQE) of the organic photosensitive layer 260.

In other words, it is possible to improve the external quantum efficiency of the organic photosensitive layer 260 by the charges aggregating at the interface of the lower charge transport layer 250 and the upper charge transport layer 270, and Forster resonant energy transfer (FRET) between the interface between the lower charge transport layer 250 and the organic photosensitive layer 260 and the interface between the upper charge transport layer 270 and the organic photosensitive layer 260.

In addition, the third electrode layer 280 may be formed on the upper charge transport layer 270. For example, the third electrode layer 280 may be a collector electrode. The third electrode layer 280 may be, for example, a transparent electrode such as ITO.

Alternatively, the third electrode layer 280 may be made of, for example, gold (Au), copper (Cu), aluminum (Al), aluminum alloy (Al-alloy), molybdenum (Mo), chromium (Cr), indium tin oxide (ITO), titanium (Ti), neodymium (AlNd), and silver (Ag) or formed as a double layer made of copper (Cu) and titanium (Ti), gold (Au) and indium tin oxide (ITO), molybdenum (Mo) and AlNd (neodymium), gold (Au) and indium tin oxide (ITO), and molybdenum (Mo) and neodymium (AlNd). The third electrode layer 280 may be formed by vacuum deposition, but is not limited thereto.

According to another embodiment of the present invention, when a voltage is applied to an anode and a cathode, holes injected from the cathode may move to the organic photosensitive layer EML 260 through the upper charge transport layer HTL 270, and electrons injected from the anode may move to the organic photosensitive layer EML 260 through the lower charge transport layer ETL 250. The holes and the electrons may generate excitons by recombining in the organic photosensitive layer EML 260. Light may be emitted when the exciton falls from an excited state to a ground state.

In order for the OPD for absorbing light, which has the above-described structure, to have excellent efficiency and/or long life, the injection and movement of the holes and the electrons should be balanced.

In another embodiment of the present invention, for the OPD, it is possible to provide an organic thin film transistor provided with the OPD including the organic photosensitive layer 260 and two or more charge transport layers ETL 250 and 270, which increase efficiency, for example, external quantum efficiency (EQE) and have a low operation voltage and long life.

A method of manufacturing the vertical organic thin film transistor according to another embodiment of the present invention formed by the above configuration will be described with reference to the accompanying drawings as follows.

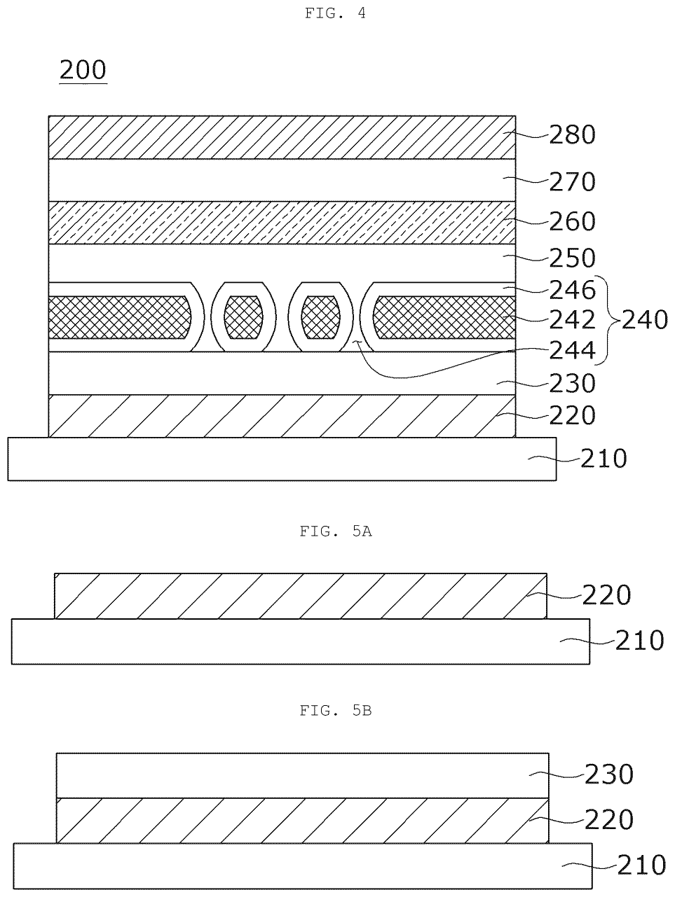

FIGS. 5A to 5E are cross-sectional views of a manufacturing process of the vertical organic thin film transistor according to another embodiment of the present invention.

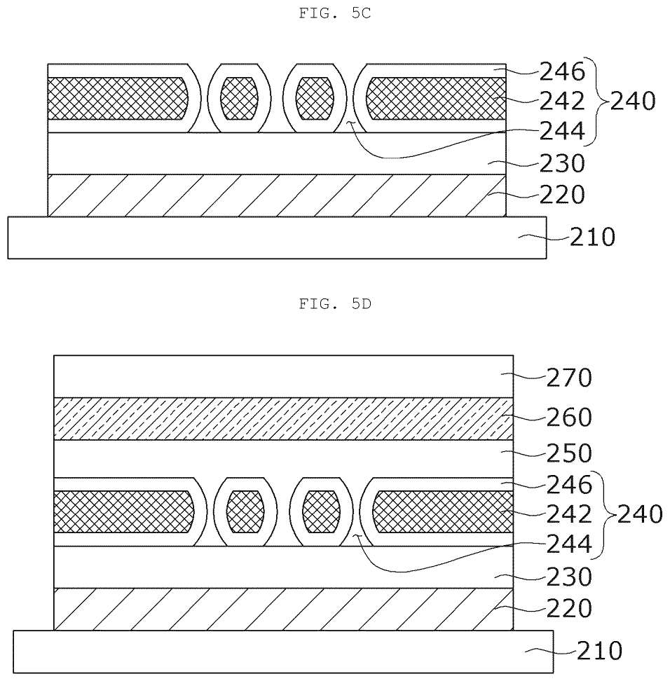

FIG. 6 is a flowchart of the manufacturing process of the vertical organic transistor according to another embodiment of the present invention.

In the method of manufacturing the organic transistor according to another embodiment of the present invention, referring to FIGS. 5A and 6, the substrate 210 is first provided (S210).

The substrate 210 may be a base for supporting the overall structure of the organic transistor 200. For example, the substrate 210 may be made of glass, quartz, polymer resin (e.g., plastic), silicone, or the like.

Next, referring to FIGS. 5A and 6, the first electrode layer 220 may be formed on the substrate 210 (S220). For example, the first electrode layer 220 may be a collector electrode. The first electrode layer 220 may be formed by using, for example, a transparent electrode material such as ITO.

Next, referring to FIGS. 5B and 6, the organic active layer 230, which is an organic semiconductor layer, may be formed on the first electrode layer 220 (S230). In this case, the organic active layer 230 may be formed along the upper surface of the first electrode layer 220.

The organic active layer 230 may have high charge mobility and may be made of a material that facilitates charge injection. The organic active layer 230 may be formed by using a semiconductor low-molecular material such as oligothiophene or pentacene or a semiconductor high-molecular material such as polythiophene or using n-type and p-type high-molecular materials and n-type and p type low-molecular materials.

Alternatively, a layer of high efficiency n-type doping W2(hpp)4 (20 nm thick, 1 wt % in C₆₀) may be applied to the organic active layer 230 for improved electron injection.

Next, referring to FIGS. 5C and 6, the second electrode layer 240 may be formed on the organic active layer 230.

The second electrode layer 240 may include a base electrode layer 242, which is a transmission electrode, a plurality of pinholes 244 formed in the base electrode layer 242 to provide a movement path of charges, and a metal oxide layer 246 surrounding the entire surface including an upper surface and a lower surface of the base electrode layer 242 and the pinholes 244.

The base electrode layer 242 may be, for example, any one of Al, Ti, Mg, Cu, Ni, Si, Cr, Hf, Sn, Y, and Zn.

In addition, the metal oxide layer 246 may contain, for example, at least one selected from the group consisting of yttrium oxide (Y₂O₃), aluminum oxide (Al₂O₃, AlOₓ, or AlₓO_{y}), magnesium oxide (MgOₓ), zinc oxide (ZnO), tin oxide (SnO), iron oxide (Fe₂O₃ or FeOₓ), titanium oxide (TiOₓ), zirconium oxide (ZrO₂), chromium oxide (Cr₂O₃), hafnium oxide (HfO), beryllium oxide (BeO), tungsten oxide (WOₓ), copper oxide (CuOₓ), silicone oxide (SiOₓ), and nickel oxide (NiOₓ) (x and y are rational numbers between 1 and 3).

In the embodiment of the present invention, a case in which the base electrode layer 242 is made of Al and the metal oxide layer 246 is made of AlOₓ is described as an example, but is not limited thereto, and it goes without saying that the vertical organic thin film transistor 200 according to the present invention may be manufactured through the above-described type of the base electrode layer 242 and the metal oxide layer 246.

The pin hole 244 may have a size of several nanometers and provide the movement path of charges between the electrode layers. The organic active layer 230 and the lower charge transport layer 250 to be described below may come into contact with each other through the pinhole 244 formed in the base electrode layer 242.

In addition, the metal oxide layer 246 may grow on an exposed surface (i.e., including a side surface of the pinhole) of the pinhole 244 by several nanometers and function as a dielectric layer on the surface of the base electrode layer 242 while maintaining the electron movement path.

Next, referring to FIGS. 5D and 6, the lower charge transport layer 250 may be formed on the second electrode layer 240 (S250). The lower charge transport layer 250 is an electron transport layer and may be a material layer having high electron mobility and light-emitting characteristics. The lower charge transport layer 250 may be a quantum dot layer, a monomolecular layer, or a polymer layer.

Next, the organic photosensitive layer 260 may be formed on the lower charge transport layer 250 (S260). Materials for the formation of the photosensitive layer 260 may include not only organic semiconductor materials such as organic low-molecular and high-molecular donor materials and organic low-molecular and high-molecular acceptor materials used in the OPD, but also CsPbBr₃, which is a perovskite quantum dot, or C₃N₄, which is a two-dimensional material.

Next, the upper charge transport layer 270 may be formed on the organic photosensitive layer 260. The upper charge transport layer 270 is a hole transport layer, a material layer having a high hole mobility characteristic, and may be a quantum dot layer, a monomolecular layer, or a polymer layer.

An energy level of the lower charge transport layer 250 is lower than that of the upper charge transport layer 270. When a voltage is applied to the lower charge transport layer 250 and the upper charge transport layer 270 according to this difference in energy level, charges (i.e., electrons/holes) aggregates (i.e. accumulates) at an interface of the upper charge transport layer 270 and the lower charge transport layer 250.

For example, the electrons aggregate at the lower charge transport layer 250 side, and the holes aggregate at the upper charge transport layer 270 side.

The aggregation of the charges can improve the binding efficiency of the electrons and the holes, thereby increasing the efficiency of the photodiode device.

Moreover, by providing the organic photosensitive layer 260 between the lower charge transport layer 250 and the upper charge transport layer 270, it is possible to increase external quantum efficiency according to the charges aggregating at the interface of the lower charge transport layer 250 and the upper charge transport layer 270. In addition, by transmitting light generated from the upper charge transport layer 150 and the lower charge transport layer 130 to the organic photosensitive layer 260, it is possible to improve the external quantum efficiency of the organic photosensitive layer 260.

In other words, it is possible to improve the external quantum efficiency of the organic photosensitive layer 260 by the charges aggregating at the interface of the lower charge transport layer 250 and the upper charge transport layer 270, and Forster resonant energy transfer (FRET) between the interface between the lower charge transport layer 250 and the organic photosensitive layer 260 and the interface between the upper charge transport layer 270 and the organic photosensitive layer 260.

Next, referring to FIGS. 5E and 6, the third electrode layer 280 may be formed on the upper charge transport layer 270. The third electrode layer 280 may be, for example an emitter electrode.

The third electrode layer 280 may be made of, for example, gold (Au), copper (Cu), aluminum (Al), aluminum alloy (Al-alloy), molybdenum (Mo), chromium (Cr), indium tin oxide (ITO), titanium (Ti), neodymium (AlNd), and silver (Ag) or formed as a double layer made of copper (Cu) and titanium (Ti), gold (Au) and indium tin oxide (ITO), molybdenum (Mo) and AlNd (neodymium), gold (Au) and indium tin oxide (ITO), and molybdenum (Mo) and neodymium (AlNd). The third electrode layer 280 may be formed by vacuum deposition, but is not limited thereto.

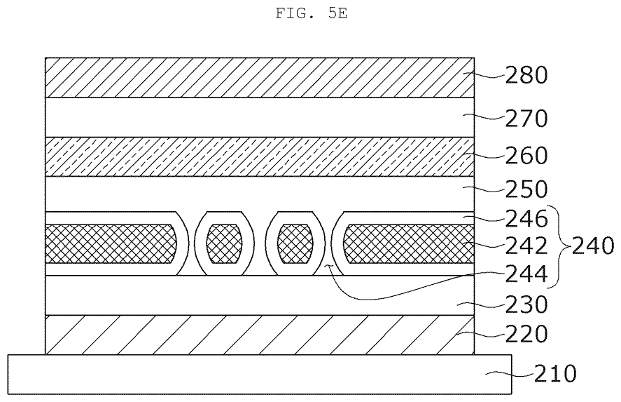

FIG. 7 is a view illustrating a change in a collector current/base current according to a base-emitter voltage of the vertical organic transistor in the embodiment of the present invention.

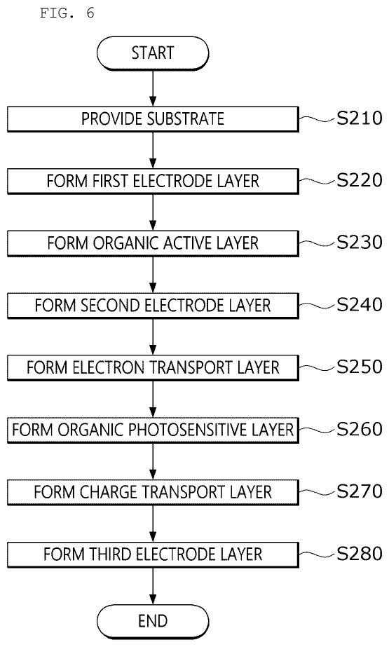

FIG. 8 is a view illustrating a change in current according to a voltage when only the OPD is present in the embodiment of the present invention.

Referring to FIG. 7, each single device was measured and measured by connecting the OPD to a drain electrode (i.e., a collector electrode) of a vertical transistor VOTFT.

At this time, a change in collector current level occurring at the same base voltage can be confirmed depending on the presence or absence of solar simulated sum (100 mW/cm²) light given to the receiving OPD.

In addition, the measurement is made by connecting the OPD device to a gate electrode (i.e., a base electrode) of the vertical organic transistor VOTFT.

At this time, a change in driving performance can be confirmed depending on the presence or absence of the solar simulated sum (100 mW/cm²) light given to the receiving OPD and a change in base voltage applied externally.

Referring to FIG. 8, as a result of performing a test in a case in which only the OPD is present, a comparative experiment between a case in which W/light was used and a case in which W/O light was used was performed.

At the time of measuring the OPD, a current voltage density (C-V curve) is measured by irradiating light or in a state of blocking external light.

When the measurement is made in the state of blocking external light, a current flow inside the device and a dark current value (degree of the current flow of the device under a condition without external light, and since the less the current flow, the lower noise it means, it is determined that the device is a high-performance device) affected by trap characteristics are confirmed, and when the measurement is made while irradiating light, the responsivity of the device to electrons generated by the light is measured.

As a result, it can be seen that a current in the case in which W/light is used appears higher than that in the case in which W/O light is used. For example, it can be seen that in the case in which W/light is used, a current is in a range of about 1×10⁻³ to 5×10⁻³ A at a voltage of 1 V or lower, and the current is in a range of about 1×10⁻² to 5×10⁻² at a voltage of 1 V or higher.

However, it can be seen that in the case in which W/O light is used, a current is in a range of about 1.0×10⁻⁷ to 2.0×10⁻⁶ A at a voltage of 0 V or lower, and the current is in a range of about 1×10⁻⁷ to 5×10⁻³ at a voltage of 0 V or higher.

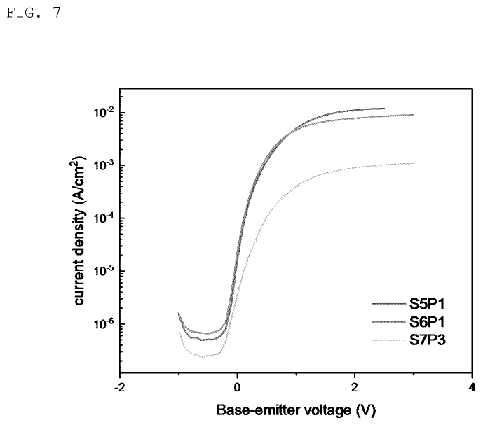

FIG. 9 is a view illustrating dark currents and photocurrents (light intensity of 100 mA/cm²) of the collector current and the base current according to the base-emitter voltage of the vertical organic transistor in the embodiment of the present invention. In particular, FIG. 9 is a view of a case in which the third electrode layer is grounded and a bias is applied to the second electrode layer and the first electrode layer.

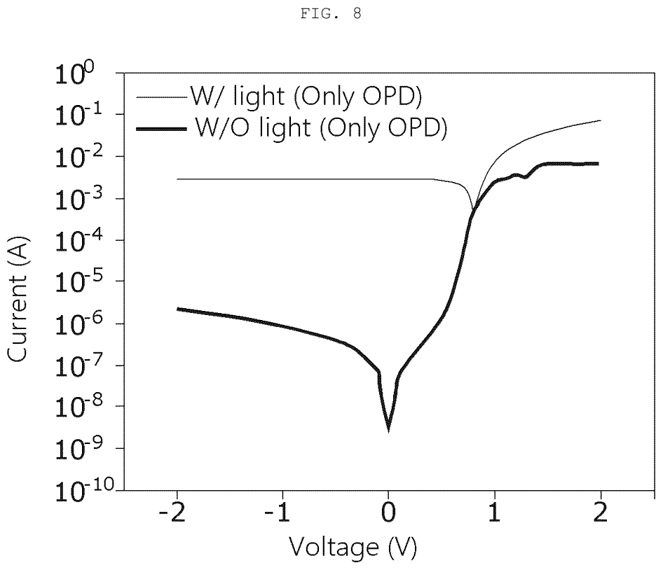

FIG. 10 is a view illustrating dark currents and photocurrents (light intensity of 100 mA/cm²) of the collector current and the base current according to the base-emitter voltage of the vertical organic transistor in the embodiment of the present invention. In particular, FIG. 10 is a view of a case in which the first electrode layer is grounded and a bias is applied to the second electrode layer and the third electrode layer.

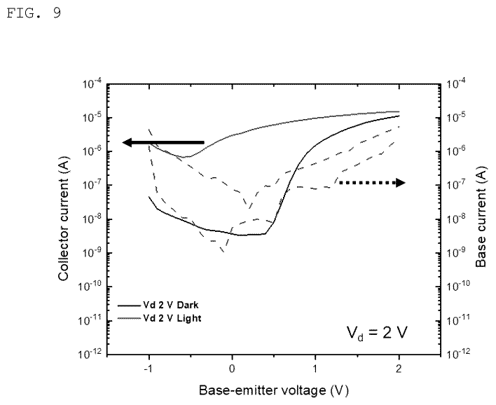

FIG. 11 is a view illustrating a drain-emitter current according to a light pulse of the vertical organic transistor over time in the embodiment of the present invention.

Referring to FIGS. 9 and 10, in FIG. 9, when there is no light, the device has a value of an OFF current of 10⁻⁹ A and a value of an ON current of 10⁻⁵ A. An ON/OFF current ratio is 10⁻⁴. A maximum current difference between the photocurrent and the dark current is 10³ times.

Since more photocurrent carriers are generated in a photoactive layer when light is supplied, the device has a threshold voltage (Vₜₕ) having a lower absolute value.

Since a potential difference between the emitter and the collector corresponding to an open circuit voltage (V_{oc}) of the OPD occurs, and charges pass through a conducting channel as photocurrent carriers, the values of the ON current and the OFF current have increased values compared to when there is no light.

In FIG. 10, when there is no light, the device is not driven, and when light is supplied, the device has the ON current of a value of about 10⁻⁵ A. In this case, since the dark current is 10⁻¹⁰ A, a current difference between the photocurrent and the dark current is 10⁵ times. This may show a difference in driving performance depending on where the emitter electrode and the collector electrode are positioned.

In FIG. 10, since the emitter electrode is positioned on a first electrode when light is not supplied, electrons may not be injected by the charge transport layer positioned next, and thus the device is not driven. When light is supplied, since the organic photosensitive layer absorbs the light to allow the photocurrent to generate carriers and allow the current to flow to the emitter electrode, a difference value between the dark current and the photocurrent at a constant voltage is about 10⁵ times.

Since the potential corresponding to the open circuit voltage (V_{oc}) of the OPD is applied to the base when light is supplied, the threshold voltage (Vₜₕ) is reduced as much as a magnitude of the voltage (V_{oc}), and an output current may increase by 10 to 100,000 times at a low applied voltage (0.01 to 2 V) compared to when there is no light.

Referring to FIG. 11, a drain-emitter current according to the light pulse of the vertical organic transistor for light detection is detected. At this time, a response time is 1.6 microseconds, and it can be seen that the vertical organic transistor is driven as a very fast optical receiving device for wireless optical communication.

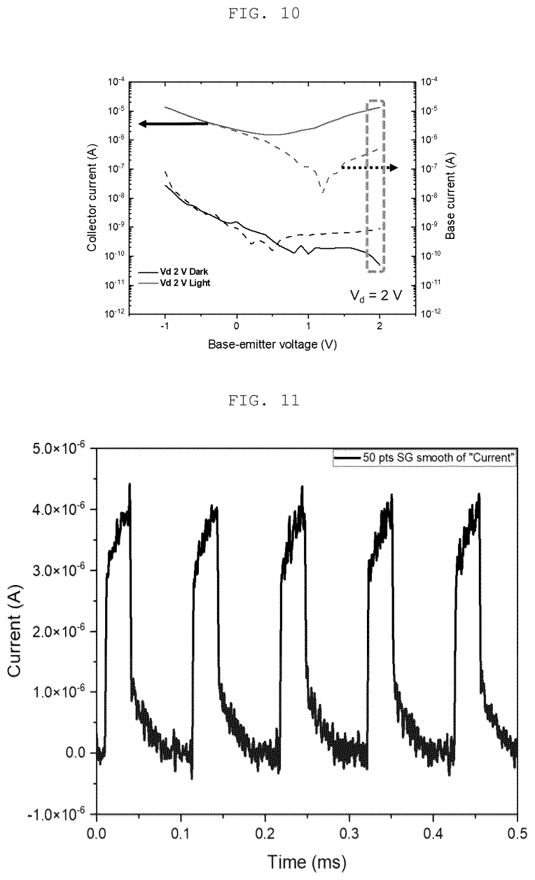

FIG. 12 is a view illustrating photosensitivity according to the base-emitter voltage of the vertical organic transistor in the embodiment of the present invention.

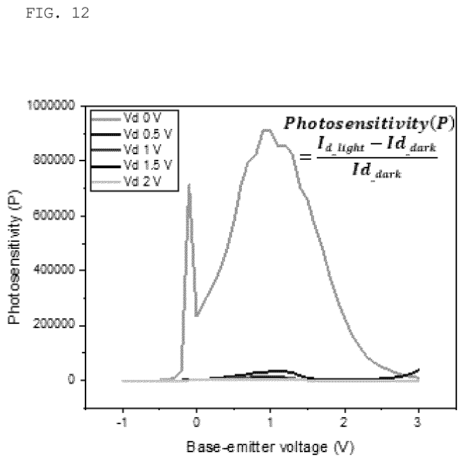

FIG. 13 is a view illustrating responsivity according to the base-emitter voltage of the vertical organic transistor in the embodiment of the present invention.

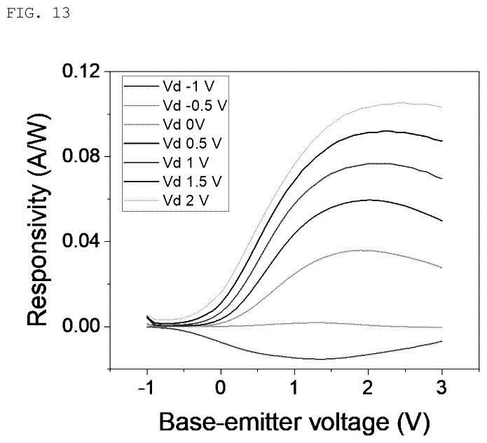

FIG. 14 is a view illustrating detectivity according to the base-emitter voltage of the vertical organic transistor in the embodiment of the present invention.

Referring to FIG. 12, the vertical organic thin film transistor including the photosensitive layer, the photosensitivity of a value from 1×10¹ to 1×10⁷ may be obtained at a low applied voltage (0.01 to 2 V).

Referring to FIGS. 13 and 14, responsivity may have a value from 1×10¹ to 6×10³ A/W, and detectivity may have 1×10¹ to 1×10¹⁶ Jonse at a low applied voltage (0.01 to 2 V).

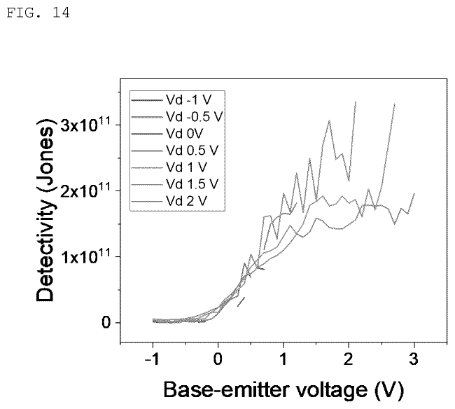

FIG. 15 is a view illustrating a frequency according to a gate voltage V_{g} of the vertical organic transistor in the embodiment of the present invention.

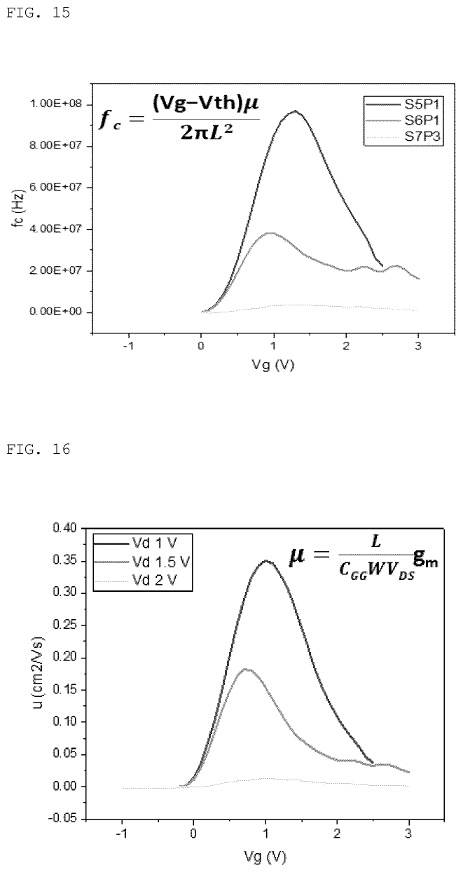

FIG. 16 is a view illustrating mobility according to the gate voltage V_{g} of the vertical organic transistor in the embodiment of the present invention.

Referring to FIGS. 15 and 16, the mobility of the vertical organic thin film transistor including the photosensitive layer may have a value from 1×10⁻⁴ to 3.51×10⁻¹ cm²/Vs, and a cutoff frequency may have a value from 100 Hz to 3 GHz at a low applied voltage (0.01 to 2 V).

According to the vertical organic transistor and the method of manufacturing the same according to the embodiments of the present invention, it is possible to secure the fast switching speed and low-power driving characteristics by vertically orientating the transistor that is present horizontally.

In addition, according to the vertical organic transistor and the method of manufacturing the same according to the embodiments of the present invention, by bonding the organic thin film transistor on the diode type device (OPD) and amplify the photocurrent of the OPD, it is possible to simultaneously achieve the high photosensitivity and detection performance characteristics as well as the fast response speed of the vertical organic thin film transistor.

The organic transistor and the method of manufacturing the same according to the present invention are not limited to the above-described effects, and other effects that are not mentioned will be able to be clearly understood by those skilled in the art to which the present invention pertains from the following description.

Although the present invention has been described above with reference to exemplary embodiments of the present invention, those skilled in the art will understand that the present invention may be modified and changed variously without departing from the spirit and scope of the present invention as described in the appended claims.

### DESCRIPTION OF REFERENCE NUMERALS

100: organic transistor
110: substrate
120: first electrode layer
130: lower charge transport layer
140: organic photosensitive layer
150: upper charge transport layer
160: second electrode layer
162: base electrode layer
164: pinhole
166: metal oxide layer
170: organic active layer
180: insulating layer
190: third electrode layer

What is claimed is:

1. A vertical organic transistor comprising:
a substrate;
a first electrode layer formed on the substrate;
a lower charge transport layer formed on the first electrode layer;
a photosensitive layer formed on the lower charge transport layer;
an upper charge transport layer formed on the photosensitive layer;
a second electrode layer including a base electrode formed on the upper charge transport layer, a plurality of pinholes formed in the base electrode and configured to provide a movement path of charges, and a metal oxide layer surrounding a surface of the base electrode and the pinholes;
an organic active layer formed on the second electrode layer; and
a third electrode layer formed on the organic active layer.

2. The vertical organic transistor of claim 1, wherein the photosensitive layer includes organic low-molecular and high-molecular donor materials, organic low-molecular and high-molecular acceptor materials, organic-inorganic hybrid perovskite materials, quantum dot materials, or 2-dimensional (2D) semiconductor materials.

3. The vertical organic transistor of claim 1, wherein the metal oxide layer includes at least one selected from the group consisting of yttrium oxide (Y₂O₃), aluminum oxide (Al₂O₃, AlOₓ, or AlₓO_{y}), magnesium oxide (MgOₓ), zinc oxide (ZnO), tin oxide (SnO), iron oxide (Fe₂O₃ or FeOₓ), titanium oxide (TiOₓ), zirconium oxide (ZrO₂), chromium oxide (Cr₂O₃), hafnium oxide (HfO), beryllium oxide (BeO), tungsten oxide (WOₓ), copper oxide (CuOₓ), silicone oxide (SiOₓ), and nickel oxide (NiOₓ) (x and y are rational numbers between 1 and 3).

4. The vertical organic transistor of claim 1, wherein the organic active layer is formed by using n-type and p-type high-molecular materials or n-type and p-type low-molecular materials.

5. The vertical organic transistor of claim 1, wherein sensitivity of the vertical organic transistor including the photosensitive layer is in a range of 1×10¹ to 1×10⁷, responsivity thereof is in a range of 1×10¹ to 6×10³ A/W, detectivity thereof is in a range of 1×10¹ to 1×10¹⁶ Jonse, mobility thereof is in a range of 1×10⁻⁴ to 3.51×10⁻¹ cm²/Vs, and a cutoff frequency is in a range of 100 Hz to 3 GHz.

6. A method of manufacturing a vertical organic transistor, comprising:
providing a substrate;
forming a first electrode layer on the substrate;
forming a lower charge transport layer on the first electrode layer;
forming a photosensitive layer on the lower charge transport layer;
forming an upper charge transport layer on the photosensitive layer;
forming a second electrode layer including a base electrode, a plurality of pinholes formed in the base electrode and configured to provide a movement path of charges, and a metal oxide layer surrounding a surface of the base electrode and the pinholes on the upper charge transport layer;
forming an organic active layer on the second electrode layer; and
forming a third electrode layer on the organic active layer.

7. The method of claim 6, wherein the photosensitive layer includes organic low-molecular and high-molecular donor materials, organic low-molecular and high-molecular acceptor materials, organic-inorganic hybrid perovskite materials, quantum dot materials, or 2-dimensional (2D) semiconductor materials.

8. The method of claim 6, wherein the metal oxide layer includes at least one selected from the group consisting of yttrium oxide (Y₂O₃), aluminum oxide (Al₂O₃, AlOₓ, or AlₓO_{y}), magnesium oxide (MgOₓ), zinc oxide (ZnO), tin oxide (SnO), iron oxide (Fe₂O₃ or FeOₓ), titanium oxide (TiOₓ), zirconium oxide (ZrO₂), chromium oxide (Cr₂O₃), hafnium oxide (HfO), beryllium oxide (BeO), tungsten oxide (WOₓ), copper oxide (CuOₓ), silicone oxide (SiOₓ), and nickel oxide (NiOₓ) (x and y are rational numbers between 1 and 3).

9. The method of claim 6, wherein the organic active layer is formed by using n-type and p-type high-molecular materials or n-type and p-type low-molecular materials.

10. The method of claim 6, wherein sensitivity of the vertical organic transistor including the photosensitive layer is in a range of 1×10¹ to 1×10⁷, responsivity thereof is in a range of 1×10¹ to 6×10³ A/W, detectivity thereof is in a range of 1×10¹ to 1×10¹⁶ Jonse, mobility thereof is in a range of 1×10⁻⁴ to 3.51×10⁻¹ cm²/Vs, and a cutoff frequency is in a range of 100 Hz to 3 GHz.

11. A vertical organic transistor comprising:
a substrate;
a first electrode layer formed on the substrate;
an organic active layer formed on the first electrode layer;
a second electrode layer including a base electrode formed on the organic active layer, a plurality of pinholes formed in the base electrode and configured to provide a movement path of charges, and a metal oxide layer surrounding a surface of the base electrode and the pinholes;
a lower charge transport layer formed on the second electrode layer;
a photosensitive layer formed on the lower charge transport layer;
an upper charge transport layer formed on the photosensitive layer; and
a third electrode layer formed on the upper charge transport layer.

12. The vertical organic transistor of claim 11, wherein the organic active layer is formed by using n-type and p-type high-molecular materials or n-type and p-type low-molecular materials.

13. The vertical organic transistor of claim 11, wherein the metal oxide layer includes at least one selected from the group consisting of yttrium oxide (Y₂O₃), aluminum oxide (Al₂O₃, AlOₓ, or AlₓO_{y}), magnesium oxide (MgOₓ), zinc oxide (ZnO), tin oxide (SnO), iron oxide (Fe₂O₃ or FeOₓ), titanium oxide (TiOₓ), zirconium oxide (ZrO₂), chromium oxide (Cr₂O₃), hafnium oxide (HfO), beryllium oxide (BeO), tungsten oxide (WOₓ), copper oxide (CuOₓ), silicone oxide (SiOₓ), and nickel oxide (NiOₓ) (x and y are rational numbers between 1 and 3).

14. The vertical organic transistor of claim 11, wherein the photosensitive layer includes organic low-molecular and high-molecular donor materials, organic low-molecular and high-molecular acceptor materials, organic-inorganic hybrid perovskite materials, quantum dot materials, or 2-dimensional (2D) semiconductor materials.

15. The vertical organic transistor of claim 11, wherein sensitivity of the vertical organic transistor including the photosensitive layer is in a range of 1×10¹ to 1×10⁷, responsivity thereof is in a range of 1×10¹ to 6×10³ A/W, detectivity thereof is in a range of 1×10¹ to 1×10¹⁶ Jonse, mobility thereof is in a range of 1×10⁻⁴ to 3.51×10⁻¹ cm²/Vs, and a cutoff frequency is in a range of 100 Hz to 3 GHz.
